(19) United States
(12) Patent Application Publication
(10) Pub. No.: US 2012/0000521 A1
(43) Pub. Date: Jan. 5, 2012

(54) Graphene Solar Cell And Waveguide

(75) Inventors: Ageeth A. Bol, Yorktown Heights, NY (US); Amal Kasry, White Plains, NY (US); Marcelo Kuroda, Woodbury, CT (US); Ahmed Maarouf, Mohegan Lake, NY (US); Glenn J. Martyna, Croton on Hudson, NY (US); Dennis M. Newns, Yorktown Heights, NY (US); Razvan A. Nistor, New York, NY (US); George S. Tulevski, White Plains, NY (US)

(73) Assignees: EGYPT NANOTECHNOLOGY CENTER, Cairo (EG); INTERNATIONAL BUSINESS MACHINES CORPORATION, Armonk, NY (US)

(21) Appl. No.: 12/828,449

(22) Filed: Jul. 1, 2010

(51) Int. Cl. H01L 31/0232

(52) U.S. Cl. 136/256; 136/252; 438/69; 257/E31.127

(57) ABSTRACT

A solar cell includes a semiconductor portion, a graphene layer disposed on a first surface of the semiconductor portion, and a first conductive layer patterned on the graphene layer, the first conductive layer including at least one bus bar portion, a plurality of fingers extending from the at least one bus bar portion, and a refractive layer disposed on the first conductive layer.

### CROSS REFERENCE TO RELATED APPLICATIONS

This application is related to co-pending application docket number YOR92010146US1, all of which is incorporated by reference herein.

### FIELD OF INVENTION

The present invention relates generally to semiconductor devices and, more particularly, to graphene solar cells.

### DESCRIPTION OF RELATED ART

Solar cells that are fabricated from amorphous silicon (a-Si) or other type of low conductivity semiconductor material often include a transparent conducting overlayer (TCO) that includes a film of Indium Tin Oxide (ITO) or Al-doped ZnO. The TCO should have relatively low resistivity and high transparency. Fabricating the film is often expensive, and the resultant films are undesirably brittle.

### BRIEF SUMMARY

In an exemplary embodiment, a solar cell includes a semiconductor portion, a graphene layer disposed on a first surface of the semiconductor portion, and a first conductive layer patterned on the graphene layer, the first conductive layer including at least one bus bar portion, a plurality of fingers extending from the at least one bus bar portion, and a refractive layer disposed on the first conductive layer.

In another exemplary embodiment, a method for forming a solar cell includes forming a graphene layer on a metallic film, forming a polymethyl-methacrylate (PMMA) layer on the graphene layer, removing the metallic film from the graphene layer, disposing the graphene layer and the PMMA layer on a first surface of a semiconductor portion such that the graphene layer contacts the first surface of the semiconductor portion, removing the PMMA layer to expose the graphene layer, forming a first conductive layer on the exposed graphene layer, forming a refractive layer on the first conductive layer, and removing a portion of the first conductive layer and the refractive layer to pattern a bus bar and a plurality of fingers in the first conductive layer and the refractive layer.

In still another exemplary embodiment, a method for forming a solar cell includes forming a copper film layer on a substrate material, forming a graphene layer on the copper film layer, disposing the graphene layer, the copper film layer, and the substrate material on a first surface of a semiconductor portion such that the graphene layer contacts the first surface of the semiconductor portion, removing the substrate material to expose copper film layer, removing a portion of the copper film layer to pattern a bus bar and a plurality of fingers in the copper film layer, and forming a refractive layer on the copper film layer.

### BRIEF DESCRIPTION OF THE SEVERAL VIEWS OF THE DRAWINGS

Referring to the exemplary drawings wherein like elements are numbered alike in the several Figures:

FIG. 1 illustrates a side cut-away view of an exemplary embodiment of a solar cell.

FIG. 2 illustrates a top view of a portion of the cell of FIG. 1.

FIGS. 3-6 illustrate an exemplary method for fabricating a solar cell.

FIGS. 7-10 illustrate an alternate exemplary method for fabricating a solar cell.

FIGS. 11A-11D illustrate graphs representing examples of simulated reflectivity over a range of incident angles for waveguide layers having a variety of thicknesses.

FIGS. 12A-12C illustrate graphs representing examples of simulated electromagnetic fields in layers of a cell with a waveguide layer thickness of 3000 nm at a variety of electromagnetic radiation incident angles.

### DETAILED DESCRIPTION

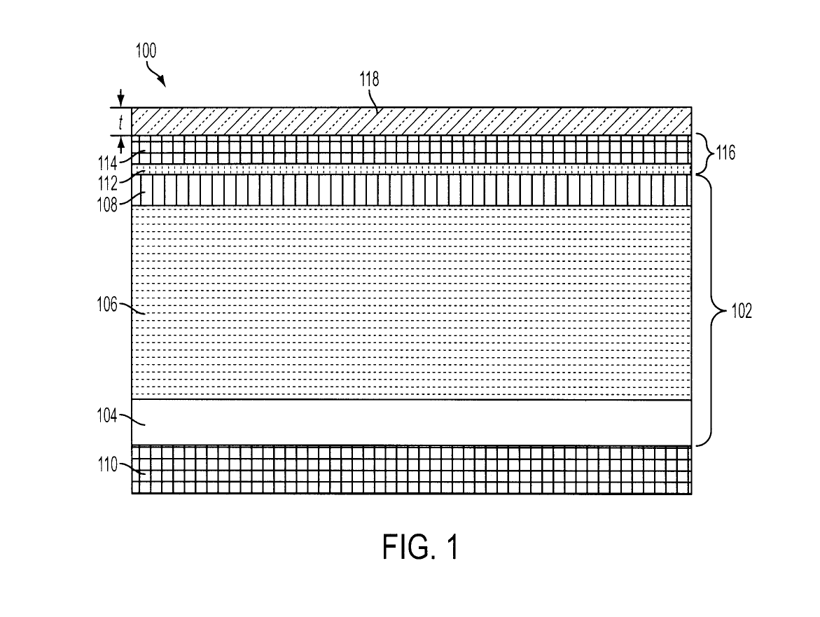

FIG. 1 illustrates a side cut-away view of an exemplary embodiment of a solar cell 100. The cell 100 includes a semiconductor portion 102 that may include, for example, amorphous silicon (a-Si) having an n-type doped region 104, an intrinsic semiconductor region 106, and a p-type doped region 108. A metallic layer 110 that may include, for example, copper, aluminum, or silver is disposed on the n-type doped region 104. A graphene layer 112 is disposed on the p-type doped region 108. A conductive bus layer 114 is disposed on the graphene layer 112 and may be patterned from a conductive metal such as, for example, copper or silver. A waveguide layer (refractive layer) 118 having a thickness (t) is disposed on the conductive bus layer 114. The thickness t may be between, for example 1000 nanometers (nm) and 5000 nm depending on the refractive index of the material used to form the waveguide layer 118. (Simulations, described below, have shown that for a waveguide layer formed from Al₂O₃, at a thickness of approximately 3000 nm yields desirable reflectivity over a range of incident angles.) The waveguide layer 118 may include a material having a high reflective index and transparency such as, for example, aluminum oxide (Al₂O₃). Other types of materials with high refractive index that may be used include transparent hybrid polymers or block copolymers. The graphene layer 112 and the conductive bus layer 114 form a transparent conducting overlayer (TCO) portion 116.

It is desirable to fabricate the cell 100 such that the transparency of the TCO layer 112 is greater than or equal to 85% with a resistance per square of less than 10 ohms. Though the graphene layer 112 satisfies the desired transparency parameters for the cell 100, the resistance of the graphene layer 112 without the conductive bus layer 114 is greater than desired. Fabricating the conductive bus layer 114 on the graphene layer 112 to form the TCO portion 116 reduces the resistivity of the TCO portion 116 to be within the desired resistance parameters while maintaining the desired transparency parameters. The use of graphene in the cell 100 may advantageously allow the cell 100 to be flexible such that the cell 100 may conform and be applied to curved surfaces.

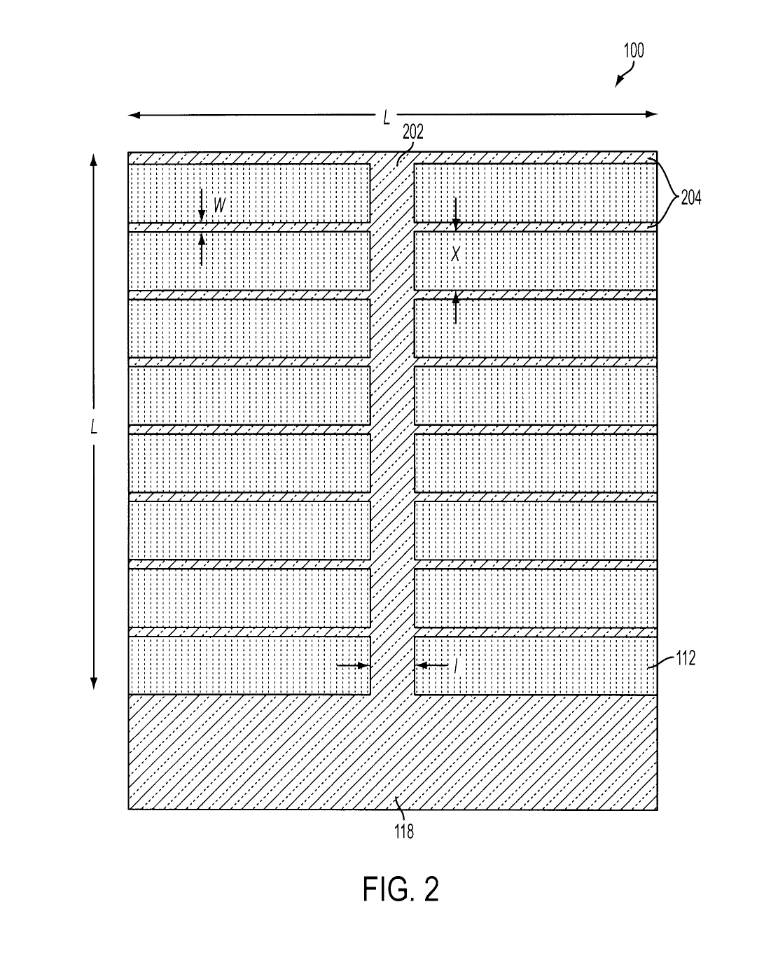

FIG. 2 illustrates a top view of a portion of the cell including the waveguide layer 118 that is patterned on the conductive bus layer 114 (of FIG. 1). The waveguide layer 118 and the conductive bus layer 114 include at least one bus portion 202 and a plurality of finger portions 204 (fingers).

In operation, the graphene layer 112 collects current from the underlying semiconductor portion 102 that produces current when exposed to electromagnetic radiation, and the conductive bus layer 114 pattern collects current from the graphene layer 112. The waveguide layer 118 that is patterned on the conductive bus layer 114 has a high refractive index that reduces losses of electromagnetic radiation due to the reflectivity of the conductive bus layer 114.

Referring to FIG. 2, to maintain transparency, the conductive bus layer 114 covers approximately 8% of the surface area of the solar cell 100. The conductive bus layer 114 has dimensions L×L, the bus portion 202 width is l, the finger 204 width is w, and the finger 204 spacing is x. Denoting by N the (number of fingers+1) on each side of a bus portion 202, N≈L/x. N=8 in the illustrated embodiment, but the number N may include any number of fingers 204. The thickness of the conductive bus layer 114 is t, and the resistivity of the metal ρ.

Assuming that the fingers 204 and the bus portion 202 (busbar) each take up 4% of the surface area, and the metal used to fabricate the conductive bus layer 114 is

$$\frac{NwL}{{L}^{2}} = \frac{w}{x} = 0.04 ,$$

for the fingers, and copper (Cu) results in:

$$\frac{Ll}{{L}^{2}} = \frac{l}{L} = 0.04 ,$$

for the busbar.

The resistance per square (R_{Cu}^{□}) of the Cu is

$${R}_{Cu}^{□} = \frac{ρ}{t} .$$

The resistance of a finger is:

$${R}_{f} = \frac{L}{2 w} {R}_{Cu}^{□} ,$$

And the total resistance due to all the fingers, as seen by the busbar 202 is

$${R}_{f}^{tot} = ( \frac{L}{2 w} ) ( \frac{1}{2 N} ) {R}_{Cu}^{□} = \frac{x}{4 w} {R}_{Cu}^{□} = \frac{25}{4} {R}_{Cu}^{□} .$$

The resistance of the busbar 202 is:

$${R}_{bb} = ( \frac{L}{l} ) {R}_{Cu}^{□} = 25 {R}_{Cu}^{□} .$$

Hence the total Cu resistance is:

$${R}_{Cu}^{tot} = ( 25 + \frac{25}{4} ) {R}_{Cu}^{□} = \frac{125}{4} {R}_{Cu}^{□} .$$

If Cu thickness t=1 um, and ρ=2×10⁻⁶ Ohm cm, the total Cu resistance is:

R_{Cu}^{tot}=0.6 Ohm.

The resistance per square is dominated by the graphene resistance R_{g}^{tot}.

### Estimated as:

$${R}_{g}^{tot} = \frac{1}{4 {N}^{2}} {R}_{g}^{□} = \frac{{x}^{2}}{4 {L}^{2}} {R}_{g}^{□} ,$$

Where R_{g}^{□} is the resistance per square of the graphene layer 112.

The Cu resistance can be ignored if the Cu thickness is approximately 1 um. The smallest in-plane dimension, the finger thickness w, is used to determine the overall pattern scale. If screen printing is used, the finger thickness may be as small as w=60 um. If w=60 um, and N=20, then:

x=0.15 cm,

L=3 cm,

l=0.12 cm.

The resistance per square is, (assuming dominance by the graphene resistance):

$${R}_{g}^{tot} = \frac{1}{4 {( 20 )}^{2}} {R}_{g}^{□} = \frac{1}{1600} {R}_{g}^{□} .$$

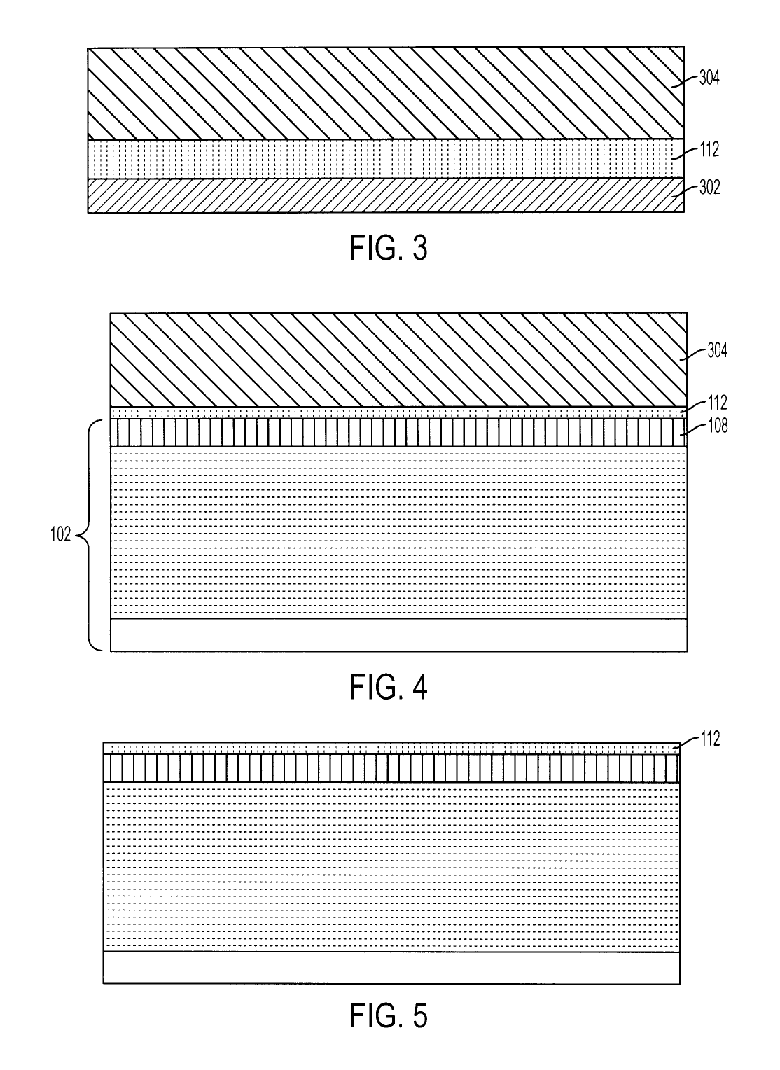

FIGS. 3-6 illustrate an exemplary method for fabricating the cell 100. Referring to FIG. 3, the graphene layer 112 is formed on a copper foil 302 with a chemical vapor deposition method (CVD) where the copper foil 302 is exposed to a carbon containing gas such as, for example, Ethylene at approximately 875° C. for approximately 30 minutes. A polymethyl-methacrylate (PMMA) layer 304 is spin coated on the graphene layer 112.

In FIG. 4, the graphene layer 112 is separated from the copper foil 302 by dissolving the copper in 1M solution of iron Chloride. The graphene layer 112 with the PMMA layer 304 is placed onto the p-type doped region 108 of the semiconductor portion 102 with the graphene in contact with the p-type doped region 108.

In FIG. 5, the PMMA layer 304 (of FIG. 4) is removed by, for example, dissolving the PMMA layer 304 in Acetone for approximately 1 hour at 80° C.

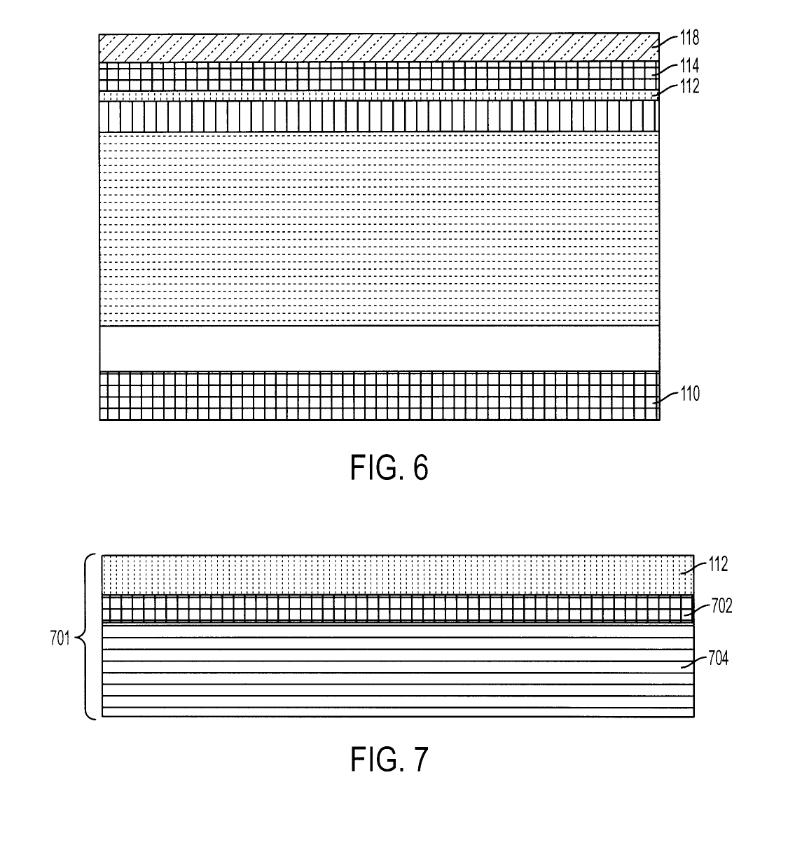

In FIG. 6, the conductive bus layer 114 is deposited on the graphene layer 112 by, for example, a lithographic masking and deposition process. The metallic layer 110 may be formed, for example, during the formation of the conductive bus layer 114, prior to the formation of the conductive bus layer 114, or following the formation of the conductive bus layer 114. The waveguide layer 118 is deposited on the conductive bus layer 114 using sputtering technique. The lithographic mask (not shown) may be removed following the formation of the waveguide layer 118.

FIGS. 7-10 illustrate an alternate exemplary fabrication method for the cell 100. Referring to FIG. 7, a 200-1000 nm thick Cu film 702 is formed on a suitable thin-film substrate 704 such as, for example, Fe. The thin-film substrate is capable of supporting the 875° C. graphene reaction temperature, and to be separable from the Cu film 702 by, for example, dissolution in a suitable solvent, which does not dissolve Cu, such as hydrochloric or sulfuric acid in the case of Fe. A graphene layer 112 is formed on the Cu film 702 by, for example, a chemical vapor deposition method (CVD) where the Cu film 702 was exposed to a carbon containing gas Ethylene at approximately 875° C. for 30 minutes.

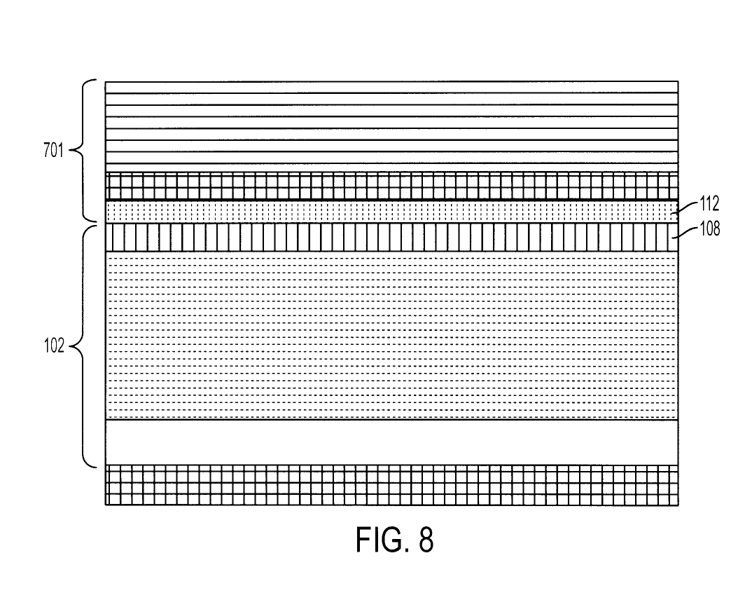

Referring to FIG. 8, the resultant Cu film 702, thin-film substrate 704, and graphene layer 112 structure 701 is placed onto the p-type doped region 108 of the semiconductor portion 102 with the graphene in contact with the p-type doped region 108.

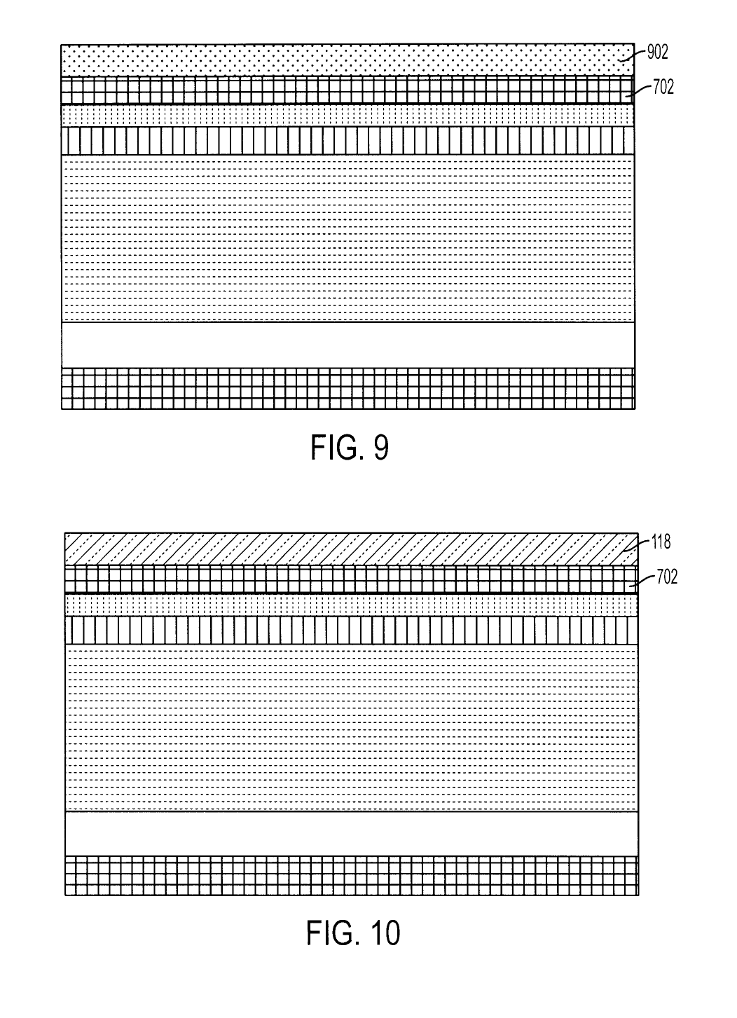

In FIG. 9, thin-film substrate 704 (of FIG. 8) is removed by, for example, dissolution in a suitable solvent, such as hydrochloric or sulfuric acid in the case of Fe. Using a process such as, for example, screen printing a resist stencil 902 (e.g. a laquer-type resist stencil) for a desired pattern of a conductive bus layer is printed onto the Cu film 702. The Cu film 702 that not covered by the lacquer resist is removed by, for example etching with a reagent such as a 1M solution of iron Chloride leaving a resultant conductive bus layer similar to the conductive bus layer 114 of FIGS. 1 and 2 described above. The resist stencil 902 may be dissolved by, for example an organic solvent.

Referring to FIG. 10, the resist stencil 902 (of FIG. 9) is removed, and the waveguide layer 118 is formed on the conductive bus layer 114. Electrodes for external contact are applied to the conductive bus layer 114 and the metallic layer 110 (of FIG. 1), and a transparent insulating protective layer (not shown) is deposited on the conductive bus layer 114.

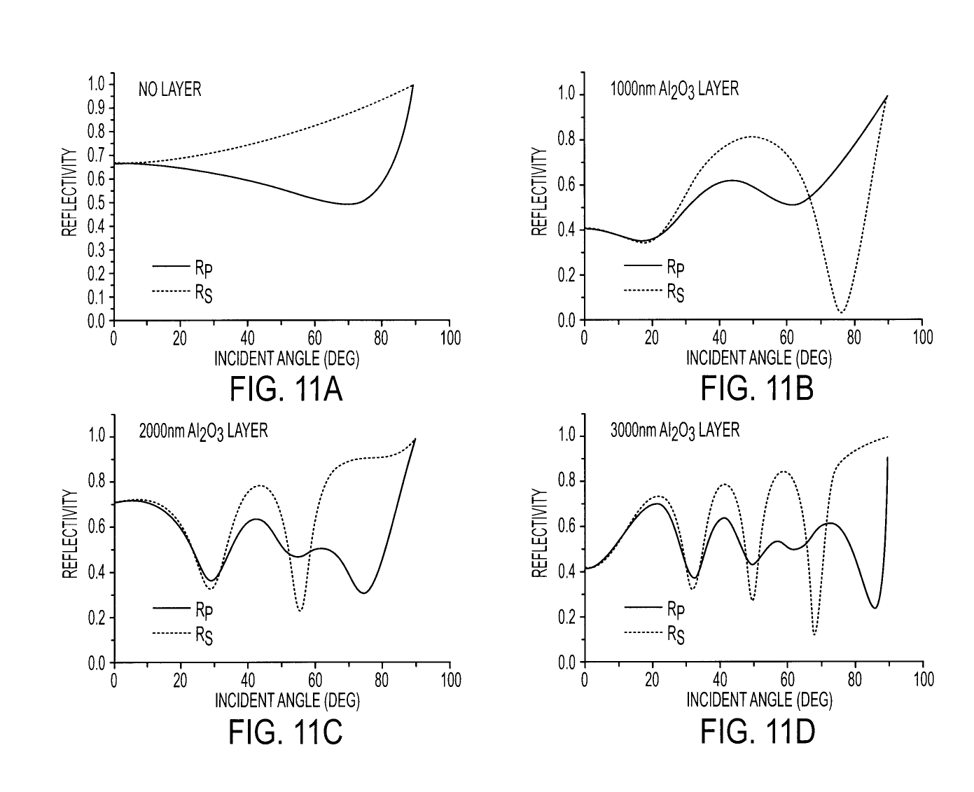

FIGS. 11A-11D illustrate graphs representing examples of simulated reflectivity over a range of incident angles for waveguide layers 118 having a variety of thicknesses (t). FIG. 11A illustrates the resultant reflectivity for a cell with no waveguide layer 118 at a range of incident angles for electromagnetic radiation that is P-polarized (Rₚ), where the electric field components lie in the plane formed by incident and reflected waves, and S-Polarized (Rₛ), where the electric field components lie perpendicular to the plane formed by incident and reflected waves. FIGS. 11B-11D illustrate the resultant reflectivity of a cell 100 (of FIG. 1) over a range of incident angles with waveguide layers 118 (fabricated with Al₂O₃) having thicknesses of 1000 nm, 2000 nm and 3000 nm respectively. Referring to FIG. 11D, the waveguide layer 118 at 3000 nm results in less reflectivity over a greater range of incident angles than the results of the simulations shown in FIGS. 11A-11C. The above described simulations show results for a wavegulde layer 118 fabricated from Al₂O₃, other materials used to form the waveguide layer 118 may have different results.

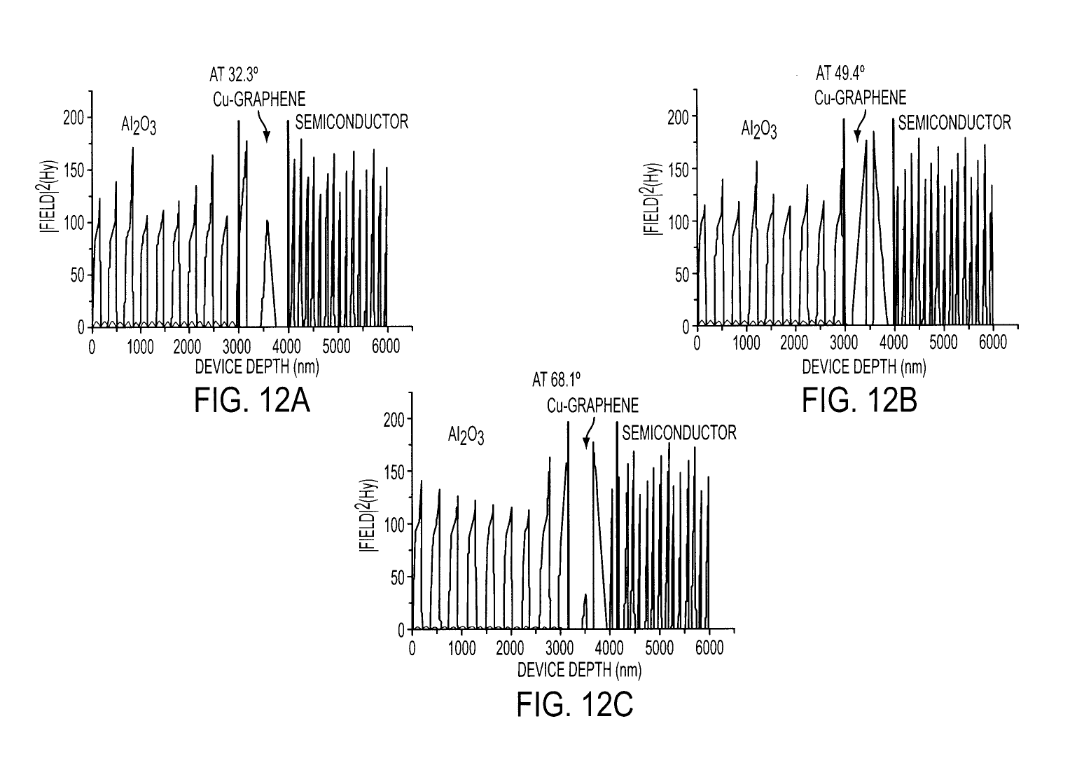

FIGS. 12A-12C illustrate graphs representing examples of simulated electromagnetic fields in layers of the cell 100 with a waveguide layer 118 thickness of 3000 nm at a variety of electromagnetic radiation incident angles (32.2°, 49.4°, and 68.1°). The FIGS. 12A-12C illustrate that the semiconductor portion 102 (semiconductor) receives a desired amount of electromagnetic radiation at a variety of incident angles.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A solar cell comprising:
a semiconductor portion;
a graphene layer disposed on a first surface of the semiconductor portion;
a first conductive layer patterned on the graphene layer, the first conductive layer including at least one bus bar portion and a plurality of fingers extending from the at least one bus bar portion; and
a refractive layer disposed on the first conductive layer.

2. The cell of claim 1, wherein the refractive layer includes an aluminum oxide (Al₂O₃) material.

3. The cell of claim 1, wherein the refractive layer has a thickness of between 500 nm and 5000 nm.

4. The cell of claim 1, wherein the first surface of the semiconductor portion includes a p-type doped region.

5. The cell of claim 1, wherein the semiconductor portion includes a second surface having an n-type doped region.

6. The cell of claim 5, wherein the cell includes a second conductive layer disposed on the second surface of the semiconductor portion.

7. The cell of claim 1, wherein the fingers and bus bar portion are operative to collect current from the graphene layer.

8. The cell of claim 1, wherein the cell first conductive layer includes copper.

9. A method for forming a solar cell, the method including:
forming a graphene layer on a metallic film;
forming a polymethyl-methacrylate (PMMA) layer on the graphene layer;
removing the metallic film from the graphene layer;
disposing the graphene layer and the PMMA layer on a first surface of a semiconductor portion such that the graphene layer contacts the first surface of the semiconductor portion;
removing the PMMA layer to expose the graphene layer;
forming a first conductive layer on the exposed graphene layer;
forming a refractive layer on the first conductive layer; and
removing a portion of the first conductive layer and the refractive layer to pattern a bus bar and a plurality of fingers in the first conductive layer and the refractive layer.

10. The method of claim 9, wherein the method further includes forming a p-typed doped region on the first surface of the semiconductor portion prior to disposing the graphene layer and the PMMA layer on the first surface of the semiconductor portion.

11. The method of claim 9, wherein the method further includes forming an n-type doped region on a second surface of the semiconductor portion.

12. The method of claim 9, wherein the refractive layer includes an aluminum oxide (Al₂O₃) material.

13. The method of claim 9, wherein the first conductive layer includes copper.

14. A method for forming a solar cell, the method including:
forming a copper film layer on a substrate material;
forming a graphene layer on the copper film layer;
disposing the graphene layer, the copper film layer, and the substrate material on a first surface of a semiconductor portion such that the graphene layer contacts the first surface of the semiconductor portion;
removing the substrate material to expose copper film layer;
removing a portion of the copper film layer to pattern a bus bar and a plurality of fingers in the copper film layer; and
forming a refractive layer on the copper film layer.

15. The method of claim 14, wherein the method further includes forming a p-typed doped region on the first surface of the semiconductor portion prior to disposing the graphene layer, the copper film layer, and the substrate material on the first surface of the semiconductor portion.

16. The method of claim 14, wherein the method further includes forming an n-type doped region on a second surface of the semiconductor portion.

17. The method of claim 16, wherein the method further includes forming a second conductive layer on the second surface of the semiconductor portion.

18. The method of claim 14, wherein the substrate material includes iron.

19. The method of claim 14, wherein the substrate material is removed using a solvent.

20. The method of claim 14, wherein the refractive layer includes an aluminum oxide (Al₂O₃) material.
